(19) United States
(12) Patent Application Publication
(10) Pub. No.: US 2011/0194267 A1
(43) Pub. Date: Aug. 11, 2011

(54) ELECTRONIC ASSEMBLY AND CASE THEREOF

(76) Inventors: Zhi-Kai Sun, TAIPEI CITY (TW); Ho-Ching Huang, TAIPEI CITY (TW); Wen-Bin Li, TAIPEI CITY (TW)

(21) Appl. No.: 12/987,162

(22) Filed: Jan. 10, 2011

(30) Foreign Application Priority Data
Feb. 11, 2010 (TW) 099104429

(51) Int. Cl. H05K 7/00

(52) U.S. Cl. 361/807

(57) ABSTRACT

This invention provides an electronic assembly and a case thereof. The electronic assembly is used in an electronic device and includes a first cover, a second cover, a plurality of components, a sealing element, and at least one fastening element. The second cover is connected with the first cover to define a containing space. The components are contained in the containing space. The sealing element is sandwiched between the first cover and the second cover and has conductive nonwoven fabric. The fastening element fastens the first cover and the second cover and compresses the conductive nonwoven fabric of the sealing element to allow the first cover to be electrically connected to the second cover. The sealing element with the conductive nonwoven fabric is disposed between the first cover and the second cover of the case in the invention for preventing the components from water and EMI.

### CROSS-REFERENCE TO RELATED APPLICATIONS

This Non-provisional application claims priority under 35 U.S.C. §119(a) on Patent Application No(s). 099104429 filed in Taiwan, Republic of China on Feb. 11, 2010, the entire contents of which are hereby incorporated by reference.

### BACKGROUND OF THE INVENTION

1. Field of the Invention

This invention relates to an electronic assembly and a case thereof and, more particularly, to a case used for containing a transformer of an industrial computer.

2. Description of the Related Art

Before manufactures sell products to consumers, they have to ask safety testing and certification institutes to test the products, thus to ensure that the products conform to international norms. The tests include a product function test and certification, a follow-up service (FUS), or an electromagnetic compatibility (EMC) test. If the product conforms to the regulations, the manufactures can sell the products to the consumers.

The EMC test includes an electromagnetic interference (EMI) test and an electromagnetic susceptibility (EMS) test. The EMI test is mainly to test whether a product generates electromagnetic waves to affect human safety, and the EMS test is to test whether a product is interfered with electromagnetic waves generated by other devices. An industry computer has a higher requirement for EMI, to prevent electromagnetic waves generated by a system from affecting human or prevent noise generated by external equipment from interfering with system elements.

In a conventional transformer case, to avoid the EMI, the manufacturers use conductive woven fabric, conductive paint, solder, or iron elements to allow noise to be grounded or shield the noise generated by the system elements.

However, if an upper cover and a lower cover of a transformer case are assembled in a dispensing mode, stability of the manufacture may be affected. The manufacturers further assemble the upper cover and the lower cover of the transformer case in a soldering mode. However, the soldering mode used for assembling the upper cover and the lower cover needs longer manufacturing time, which is not suitable for large manufacturing and is also failing to rework. As far as other materials such as conductive woven fabric, conductive paint, conductive foam, or conductive rubber, the longer manufacturing time and higher costs still exist, or the impedance is too high to conform to MIL-STD-461E regulations in an industrial computer.

### BRIEF SUMMARY OF THE INVENTION

This invention provides an electronic assembly and a case thereof capable of being effectively waterproof, avoiding electromagnetic interference, improving assembling convenience, increasing manufacturing efficiency, and reworking.

This invention provides an electronic assembly used in an electronic device. The electronic assembly includes a first cover, a second cover, a plurality of components, a sealing element, and at least one fastening element. The second cover is connected with the first cover to define a containing space. The components are contained in the containing space. The sealing element is sandwiched between the first cover and the second cover, and the sealing element has conductive nonwoven fabric. The fastening element fastens the first cover and the second cover and compresses the conductive nonwoven fabric of the sealing element to allow the first cover to be electrically connected to the second cover.

This invention provides a case for containing a plurality of components of an electronic assembly of an electronic device. The case includes a first cover, a second cover, a sealing element, and at least one fastening element. The second cover is connected with the first cover to define a containing space, and the components are contained in the containing space. The sealing element is sandwiched between the first cover and the second cover, and the sealing element has conductive nonwoven fabric. The fastening element fastens the first cover and the second cover and compresses the conductive nonwoven fabric of the sealing element to allow the first cover to be electrically connected to the second cover.

In one embodiment of the invention, a compression amount of the sealing element may be between 30% and 40%.

In one embodiment of the invention, an impedance of the sealing element may be between 0.01Ω and 0.05Ω.

In one embodiment of the invention, the conductive nonwoven fabric may include plant fabric.

In one embodiment of the invention, the conductive nonwoven fabric may include iron, nickel, organic phosphorus compounds, or a combination thereof.

In one embodiment of the invention, the fastening element may fasten the first cover and the second cover in a screwing mode, a clamping mode, or a hooking mode

In one embodiment of the invention, the sealing element may be an elastic sealing element.

In one embodiment of the invention, the first cover may have a first connecting portion, and the second cover may have a second connecting portion. The second connecting portion of the second cover is connected with the first connecting portion of the first cover, and the sealing element is sandwiched between the first connecting portion and the second connecting portion.

In one embodiment of the invention, the first connecting portion and the second connecting portion may be a protrudent portion and a recessed portion, an inclined surface and an inclined surface, a rough surface and a rough surface, or a combination thereof, respectively.

According to the electronic assembly and the case thereof in the invention, the sealing element is sandwiched between the first cover and the second cover. The sealing element has the conductive nonwoven fabric, and the first cover and the second cover compress the sealing element to a certain degree, thus allowing the first cover to be electrically connected to the second cover. In addition, the sealing element is waterproof and can effectively prevent the components of the electronic assembly from suffering external EMI. In addition, the fastening element fastens the first cover and the second cover to compress the sealing element sandwiched therebetween, thereby improving assembling convenience, improving manufacturing efficiency, and facilitating detachment to conform to rework requirements.

These and other features, aspects, and advantages of the present invention will become better understood with regard to the following description, appended claims, and accompanying drawings.

### BRIEF DESCRIPTION OF THE DRAWINGS

FIG. 1 is a schematic diagram showing an electronic assembly according to one preferred embodiment of the invention;

FIG. 2 is an exploded diagram showing an electronic assembly according to one preferred embodiment of the invention; and

FIG. 3 is another schematic diagram showing an electronic assembly according to one preferred embodiment of the invention.

### DETAILED DESCRIPTION OF THE INVENTION

An electronic assembly and a case thereof in one preferred embodiment of this invention are described hereinbelow according to the drawings, and the same elements are marked by the same reference numbers.

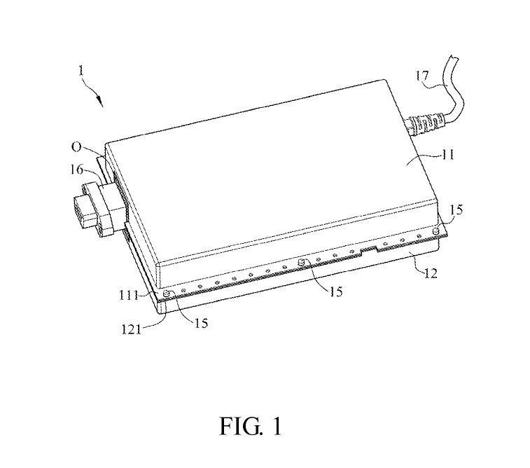

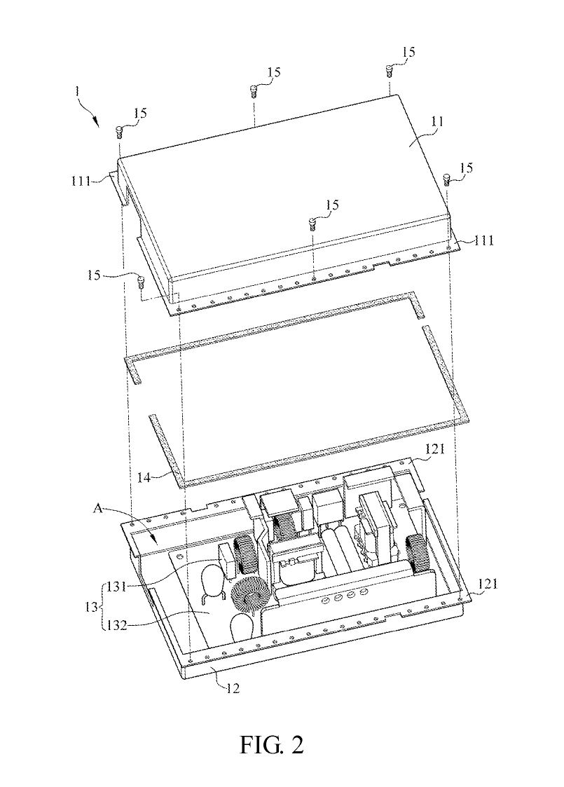

FIG. 1 is a schematic diagram showing an electronic assembly according to one preferred embodiment of the invention. FIG. 2 is an exploded diagram showing an electronic assembly according to one preferred embodiment of the invention. In the embodiment, an electronic assembly 1 is used in an electronic device (not shown). The electronic device may be an industrial computer, and the electronic assembly 1 may be a transformer. The electronic assembly 1 includes a first cover 11, a second cover 12, a plurality of components 13, a sealing element 14, and a plurality of fastening elements 15. In addition, in the embodiment, the electronic assembly 1 further includes a connector 16 and a cable 17. In FIG. 2, for clear description, the connector and the cable are not shown. In a practical structure, the electronic assembly 1 should include the connector and the cable.

The first cover 11 and the second cover 12 include a first connecting portion 111 and a second connecting portion 121, respectively. The first connecting portion 111 and the second connecting portion 121 are disposed at the periphery of the first cover 11 and the second cover 12, respectively. The second cover 12 corresponds to the first cover 11. The second connecting portion 121 of the second cover 12 is connected with the first connecting portion 111 of the first cover 11. The first cover 11 and the second cover 12 define a containing space A, and the containing space A is used for containing the components 13. In the embodiment, the first cover 11 and the second cover 12 are a recessed cover, respectively. However, the invention is not limited thereto. The containing space A may also be only formed at the first cover 11 or the second cover 12, and the components 13 may also be contained therein. The first cover 11 and the second cover 12 are conductive, and they may be made of metal, to electrically connect the first cover 11 and the second cover 12 when they are connected with each other. To stable the connected first cover 11 and the second cover 12, the first connecting portion 111 and the second connecting portion 121 can be a protrudent portion and a recessed portion, an inclined surface and an inclined surface, a rough surface and a rough surface, or a combination thereof, respectively. The design of the inclined surfaces provides greater connecting and compressing force via increasing contacting areas. In the embodiment, the first connecting portion 111 and the second connecting portion 121 are flat surfaces and have a plurality of holes.

The components 13 are contained in the containing space A. That is, the containing space A defined by the first cover 11 and the second cover 12 is used for containing the components 13 in the embodiment. The components 13 include a transformer element 131 and a circuit board 132. The transformer element 131 is disposed on the circuit board 132. The components 13 are used for modulating voltages (boosting voltages or dropping voltages) to supply operating voltages needed by the electronic device. In the embodiment, according to the sizes of the components 13, the first cover 11 and the second cover 12 with different sizes are designed to satisfy customized needs. Preferably, the size of the first cover 11 matches that of the second cover 12.

The sealing element 14 is disposed between the first cover 11 and the second cover 12. Since the second connecting portion 121 of the second cover 12 in the embodiment is connected with the first connecting portion 111 of the first cover 11, and the sealing element 14 surrounds the periphery of the first cover 11 and the second cover 12, i.e., the sealing element 14 is sandwiched between the first connecting portion 111 of the first cover 11 and the second connecting portion 121 of the second cover 12, the first cover 11 is connected with the second cover 12 via the sealing element 14.

The sealing element 14 has conductive nonwoven fabric. In a preferred embodiment of the present invention, the conductive nonwoven fabric consists of nonconductive materials and conductive materials. The nonconductive materials may include plant fabric (such as cotton fabric), and the conductive materials may include iron, nickel, organic phosphorus compounds, or a combination thereof. The nonconductive materials will match with the proper conductive materials to form the conductive nonwoven fabric according to length, thickness, physical and chemical characteristics of the plant fabric. In addition, the sealing element 14 can further has conductive adhesive and release paper in the preferred embodiment. The releaser paper is made of base paper, and the conductive adhesive is disposed between the conductive nonwoven fabric and the release paper. After the release paper is torn from the sealing element 14, the sealing element 14 can allow the conductive nonwoven fabric to be attached to the first connecting portion 111 of the first cover 11 via the conductive adhesive, and the first cover 11 is then fastened to the second cover 12 to compress the conductive nonwoven fabric. On the other hand, the conductive nonwoven fabric can also be attached to the second connecting portion 121 of the second cover 12. However, the invention is not limited thereto.

In one preferred embodiment, the thickness of the conductive nonwoven fabric is between 0.35 mm and 0.55 mm; the thickness of the conductive adhesive is about 0.055 mm±0.005; the thickness of the release paper is about 0.13 mm±0.03. In the embodiment, when a compression amount of the sealing element 14 is between 30% and 40%, the sealing element 14 has the best conductivity. An impendence of the sealing element is between 0.01Ω and 0.05Ω, and preferably it is between 0.02Ω and 0.04Ω.

In addition, a shielding ratio of the electromagnetic wave of the sealing element 14 is 90 to 100 dB when an electromagnetic wave is 10 MHz, and the shielding ratio of the electromagnetic wave of the sealing element 14 is 85 to 90 dB when the electromagnetic wave is 1 GHz. The longitudinal expanding strength of the sealing element 14 is 9.6, and the transversal expanding strength is 24 or 26.4.

In addition, the sealing element 14 is an elastic sealing element. The sealing element 14 can avoid electromagnetic interference, be waterproof, and be conveniently manufactured. When the sealing element 14 is attached to the first cover 11 or the second cover 12 in a strip-shaped size, curl and deformation may not affect the manufacture.

After compressed, the conductive materials of the sealing element 14 are close to each other to contact each other further to generate an conduction effect, thus allowing the first cover 11 and the second cover 12 to be electrically connected with each other via the sealing element 14. When the first cover 11 and the second cover 12 compress the sealing element 14 to a certain degree, the sealing element 14 can electrically connect the first cover 11 and the second cover 12. When the compression amount of the sealing element 14 is between 30% and 40%, the generated conduction effect is best. In addition, in the embodiment, besides improving manufacturing stability, the sealing element 14 can further ensure that the compression amount of the first cover 11 is equal to that of the second cover 12, such that the conduction degree of the first cover 11 can be the same as that of the second cover 12.

The fastening element 15 fastens the first cover 11 and the second cover 12. In the embodiment, a plurality of fastening elements 15 is taken for example. However, the invention is not limited thereto. The fastening elements 15 pass through corresponding holes at the periphery of the first connecting portion 111 and the second connecting portion 121 to fasten the first connecting portion 111 and the second connecting portion 121 and to compress the sealing element 14. When the sealing element 14 is compressed to a certain degree (such as between 30% and 40%), the first cover 11 and the second cover 12 can be electrically connected with each other via the sealing element 14. The fastening elements 15 fasten the first cover 11 and the second cover 12, thereby improving the assembling convenience, facilitating detachment to satisfy requirements of rework (such as replacing internal components), and satisfying customized needs.

The fastening elements 15 can fasten the first connecting portion 111 and the second connecting portion 121 in a screwing mode, a clamping mode, or a hooking mode to compress the sealing element 14. In the screwing mode, the fastening elements 15 pass through the first connecting portion 111, the sealing element 14, and the second connecting portion 121 in order. In the clamping mode, a C-shaped clamp may be used for clamping the first connecting portion 111 and the second connecting portion 121 to provide clamping force and to compress the sealing element 14. In the hooking mode, the first cover 11 may have at least one hook (not shown) at the periphery, and the length of the hook may be smaller than the thickness of the sealing element 14. When the hook of the first cover 11 directly hooks the second cover 12, the first cover 11 and the second cover 12 compress the sealing element 14 together. Otherwise, the second cover 12 can have a hook corresponding to the hook of the first cover 11. When the hook of the first cover 11 hooks the hook of the second cover 12, the first cover 11 and the second cover 12 can still compress the sealing element 14 together. In the embodiment, the fastening elements 15 fasten the first connecting portion 111 of the first cover 11 and the second connecting portion 121 of the second cover 12 in the screwing mode. However, the invention is not limited thereto.

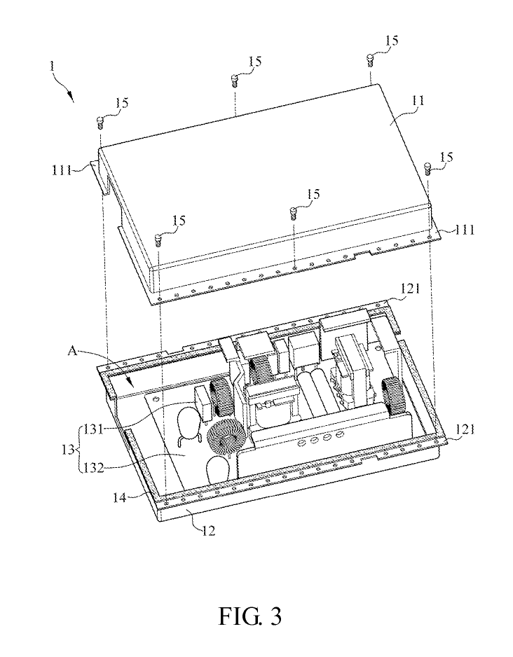

Please refer to FIG. 2 and FIG. 3 together. FIG. 3 is another schematic diagram showing an electronic assembly according to one preferred embodiment of the invention. In the embodiment, the components 13 are disposed in the containing space A of the second cover 12. The sealing element 14 is disposed at the periphery of the second connecting portion 121. The first cover 11 is disposed above the second cover 12 and the sealing element 14, and the fastening elements 15 are used to fasten the first cover 11 and the second cover 12. The fastening elements 15 provide compressing force to allow the first connecting portion 111 and the second connecting portion 121 to compress the sealing element 14 thus allowing the sealing element 14 to seal the connecting place of the first cover 11 and the second cover 12.

Since the sealing element 14 in the embodiment has conductivity after compressed, the first cover 11 can be electrically connected with the second cover 12 via the sealing element 14. When the compression amount of the sealing element 14 may be between 30% and 40%, the generated conduction effect is best. In assembling, the compression amount of the sealing element 14 can be determined via the gap between the first cover 11 and the second cover 12, and other equipment or devices can be used to ensure the compression amount of the sealing element 14.

Please refer to FIG. 1 again. In the embodiment, the electronic assembly 1 further includes a connector 16 and a cable 17. The connector 16 and the cable 17 are disposed at an opening O formed after the first cover 11 is connected with the second cover 12 and are electrically connected with the components 13. The connecting places of the connector 16, the cable 17, the first cover 11, and the second cover 12 are filled or surrounded by the sealing element to avoid EMI. According to the electronic assembly 1 in the embodiment, commercial power or power supplied by a power supply module (not shown) is transferred to the components 13 via the cable 17. After the components 13 convert the voltages, the connector 16 provides needed power to electronic products connected thereto.

This invention further discloses a case for containing a plurality of components 13 of an electronic assembly of an electronic device. The case includes a first cover 11, a second cover 12, a sealing element 14, and a plurality of fastening elements 15. The second cover 12 is connected with the first cover 11 to define a containing space A, and the components 13 are contained in the containing space A. The sealing element 14 is sandwiched between the first cover 11 and the second cover 12, and the sealing element 14 has conductive nonwoven fabric. The fastening elements 15 fasten the first cover 11 and the second cover 12 and compress the conductive nonwoven fabric of the sealing element 14 to allow the first cover 11 to be electrically connected to the second cover 12. The first cover 11, the second cover 12, the sealing element 14, and the fastening elements 15 are described as above. Therefore, they are not described for a concise purpose.

To sum up, according to the electronic assembly and the case thereof in the invention, the sealing element is sandwiched between the first cover and the second cover, and the sealing element has the conductive nonwoven fabric. When the first cover and the second cover compress the sealing element to a certain degree, the first cover and the second cover can be electrically connected with each other via the sealing element. For example, when the compression amount of the sealing element is between 30% and 40%, the generated conduction effect is best. In addition, the sealing element is waterproof and can effectively prevent the components of the electronic assembly from suffering external EMI. In addition, the fastening elements fasten the first cover and the second cover, thereby improving assembling convenience, improving manufacturing efficiency, facilitating detachment to conform to rework requirements, and satisfying customized needs.

Although the present invention has been described in considerable detail with reference to certain preferred embodiments thereof, the disclosure is not for limiting the scope of the invention. Persons having ordinary skill in the art may make various modifications and changes without departing from the scope and spirit of the invention. Therefore, the scope of the appended claims should not be limited to the description of the preferred embodiments described above.

What is claimed is:

1. An electronic assembly used in an electronic device, the electronic assembly comprising:
a first cover;
a second cover connected with the first cover to define a containing space;
a plurality of components contained in the containing space;
a sealing element sandwiched between the first cover and the second cover, the sealing element having conductive nonwoven fabric; and
at least one fastening element fastening the first cover and the second cover and compressing the conductive nonwoven fabric of the sealing element to allow the first cover to be electrically connected to the second cover.

2. The electronic assembly according to claim 1, wherein the electronic assembly is a transformer.

3. The electronic assembly according to claim 1, wherein the electronic device is an industrial computer.

4. The electronic assembly according to claim 1, wherein a compression amount of the sealing element is between 30% and 40%.

5. The electronic assembly according to claim 1, wherein an impedance of the sealing element is between 0.01Ω and 0.05Ω.

6. The electronic assembly according to claim 1, wherein the conductive nonwoven fabric comprises plant fabric.

7. The electronic assembly according to claim 1, wherein the conductive nonwoven fabric comprises iron, nickel, organic phosphorus compounds, or a combination thereof.

8. The electronic assembly according to claim 1, wherein the fastening element fastens the first cover and the second cover in a screwing mode, a clamping mode, or a hooking mode.

9. The electronic assembly according to claim 1, wherein the sealing element is an elastic sealing element.

10. The electronic assembly according to claim 1, wherein the first cover has a first connecting portion, the second cover has a second connecting portion, the second connecting portion of the second cover is connected with the first connecting portion of the first cover, and the sealing element is sandwiched between the first connecting portion and the second connecting portion.

11. The electronic assembly according to claim 10, wherein the first connecting portion and the second connecting portion are a protrudent portion and a recessed portion, an inclined surface and an inclined surface, a rough surface and a rough surface, or a combination thereof, respectively.

12. A case for containing a plurality of components of an electronic assembly of an electronic device, the case comprising:
a first cover;
a second cover connected with the first cover to define a containing space, the components contained in the containing space;
a sealing element sandwiched between the first cover and the second cover, the sealing element having conductive nonwoven fabric; and
at least one fastening element fastening the first cover and the second cover and compressing the conductive nonwoven fabric of the sealing element to allow the first cover to be electrically connected to the second cover.

13. The case according to claim 12, wherein a compression amount of the sealing element is between 30% and 40%.

14. The case according to claim 12, wherein an impedance of the sealing element is between 0.01Ω and 0.05Ω.

15. The case according to claim 12, wherein the conductive nonwoven fabric comprises plant fabric.

16. The case according to claim 12, wherein the conductive nonwoven fabric comprises iron, nickel, organic phosphorus compounds, or a combination thereof.

17. The case according to claim 12, wherein the fastening element fastens the first cover and the second cover in a screwing mode, a clamping mode, or a hooking mode.

18. The case according to claim 12, wherein the sealing element is an elastic sealing element.

19. The case according to claim 12, wherein the first cover has a first connecting portion, the second cover has a second connecting portion, the second connecting portion of the second cover is connected with the first connecting portion of the first cover, and the sealing element is sandwiched between the first connecting portion and the second connecting portion.

20. The case according to claim 19, wherein the first connecting portion and the second connecting portion are a protrudent portion and a recessed portion, an inclined surface and an inclined surface, a rough surface and a rough surface, or a combination thereof, respectively.

21. The case according to claim 12, wherein the electronic assembly is a transformer.

22. The case according to claim 12, wherein the electronic device is an industrial computer.
